(19) United States
(12) Patent Application Publication
(10) Pub. No.: US 2026/0275531 A1
(43) Pub. Date: Sep. 17, 2026

(54) MULTILAYER COATING FOR HIGH STRESSED METAL PIECES

(71) Applicant: Nuovo Pignone Tecnologie - S.r.l., Florence (IT)

(72) Inventors: Michelangelo BELLACCI, Florence, Firenze (IT); Alice PRANZETTI, Florence, Firenze (IT); Serena CINOTTI, Florence, Firenze (IT); Angelo DONATO, Florence, Firenze (IT); Alberto GUGLIELMO, Florence, Firenze (IT)

(21) Appl. No.: 19/168,158

(22) PCT Filed: Mar. 22, 2024
(86) PCT No.: PCT/EP2024/025124

§ 371 Date: Sep. 23, 2025

(30) Foreign Application Priority Data
Mar. 28, 2023 (IT) 102023000005895

(51) Int. Cl. C23C 30/00; C23C 16/32; C23C 16/34; C23C 16/40; C23C 16/513; C23C 28/04; F01D 5/28

(52) U.S. Cl. CPC C23C 30/005; C23C 16/32; C23C 16/34; C23C 16/402; C23C 16/403; C23C 16/513; C23C 28/042; F01D 5/284; F01D 5/288; F05D 2230/314; F05D 2300/121; F05D 2300/2263; F05D 2300/228

(57) ABSTRACT

The multilayer coating for a metal piece, in particular a turbomachinery component, more in particular a turbomachinery impeller, comprising a first layer which is applied on at least a portion of the metal piece and which has a hydrogen diffusion coefficient of less than 10⁻⁷ m²/s even when subjected to stress (the hydrogen diffusion coefficient being measured through a hydrogen permeation test), and a second layer which is applied on top of the first layer and which is exposed to a process fluid comprising hydrogen. The second layer comprises an oxide chosen between: aluminum oxide (Al2O3), titanium dioxide (TiO2) and silicon dioxide (SiO2). The first and the second layer and may be applied according to various depositing process techniques at temperature below 500° C.

### TECHNICAL FIELD

The subject-matter disclosed herein relates to a multilayer coating for a metal piece, in particular in a turbomachinery component, more in particular a turbomachinery impeller, and a method to prevent hydrogen diffusion in a metal piece, in particular in a turbomachinery component, more in particular a turbomachinery impeller.

### BACKGROUND ART

Turbomachinery components for hydrogen (═H2) processing, especially rotary parts, are typically made of materials that are easily subject to embrittlement in case of direct contact to hydrogen. In fact, hydrogen is a small molecule that can also split into atomic hydrogen. Hydrogen atoms may enter (i.e. diffuse) into tiny cavities of the metal structure and settle there, increasing the risk of cracks formation in the material.

In order to prevent corrosion and/or improve resistance of a metal piece, a protective coating may be applied on the surface of metal piece. However, traditional coatings have drawbacks when applied on rotary components, in particular on impellers: in fact, the complex geometry of the piece makes the coating process particularly challenging. Moreover, base material, in particular high strength steel, of high rotary speeds components cannot be coated at high temperature (i.e. temperatures >500° C.) to do not affect the metallic microstructure of base material. In addition, the high rotary speeds of the impeller during operational use cause high strain in the metal piece, causing it to stretch. Therefore, due to a non-perfect coating and/or cracking of the coating (which may not resist to the stretch of the piece), portions of the metal surface can be exposed to hydrogen, thus allowing hydrogen to diffuse within the piece.

Therefore, to process a fluid comprising hydrogen (eventually a fluid comprising 100% of hydrogen), it would be desirable to have an efficient hydrogen diffusion barrier, in particular deposited at temperature below 500° C. (in order to do not affect microgeometry of the piece) and resistant to stress and strain during operation, to prevent metal pieces from embrittlement, in particular in case of high strain caused by centrifugal speeds of rotary parts.

### SUMMARY

According to an aspect, the subject-matter disclosed herein relates to a multilayer coating for a metal piece, in particular a turbomachinery component, more in particular a turbomachinery impeller, comprising a first layer which is applied on at least a portion of the metal piece and which has a hydrogen diffusion coefficient of less than 10⁻⁷ m²/s even when subjected to stress (the hydrogen diffusion coefficient being measured through a hydrogen permeation test), and a second layer which is applied on top of the first layer and which is exposed to a process fluid comprising hydrogen. The second layer comprises an oxide chosen between: aluminum oxide (Al2O3), titanium dioxide (TiO2) and silicon dioxide (SiO2). The first layer and the second layer are applied at temperature below 500° C.

According to another aspect, the subject-matter disclosed herein relates to a method to prevent hydrogen diffusion in a metal piece, in particular in a turbomachinery component, more in particular a turbomachinery impeller, comprising the steps of:
a. applying a first layer on at least a portion of the metal piece using a technique chosen between: spray, physical vapor deposition (PVD) and chemical vapor deposition (CVD), the first layer being made of a first material low-permeable to hydrogen, and
b. applying a second layer on the first layer, the second layer being made of a second material being anti-oxidation and/or anti-corrosion and/or anti-erosion,
   the application of step “a” and the application of step “b” being performed at temperature below 500° C.

### BRIEF DESCRIPTION OF THE DRAWINGS

A more complete appreciation of the disclosed embodiments of the invention and many of the attendant advantages thereof will be readily obtained as the same becomes better understood by reference to the following detailed description when considered in connection with the accompanying drawings, wherein:

FIG. 1 shows a simplified diagram of an embodiment of an innovative multilayer coating for a metal piece,

FIG. 2 shows a flow chart of an innovative method to prevent hydrogen diffusion in a metal piece, and

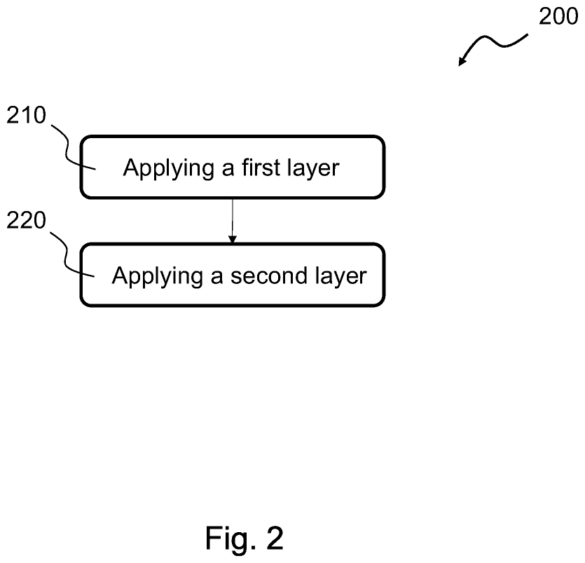

FIG. 3 shows an embodiment of an impeller which may comprise the innovative multilayer coating of FIG. 1.

### DETAILED DESCRIPTION OF EMBODIMENTS

According to an aspect, the subject-matter disclosed herein relates to a hydrogen diffusion barrier to be provided on a metal piece that is subject to high stresses such as for example an impeller of a turbomachine which rotates at high rotating speed. The hydrogen diffusion barrier is made of a two-layer coating in which the first one is applied directly on the metal impeller and prevents most of hydrogen diffusion even when subjected to stress, i.e. during operation of the impeller and/or after operation of the impeller, due to capability to follow the deformation of metallic substrate without evidencing cracks. The second one is applied on the first layer and comprises an oxide chosen between: aluminum oxide (Al2O3), titanium dioxide (TiO2) and silicon dioxide (SiO2). The second layer may still have a very low hydrogen diffusion coefficient when non interrupted (i.e. cracked), but has also low resistance to strain, therefore being often subjected to cracking which affects the overall hydrogen diffusion coefficient. The second layer prevents even corrosion and/or oxidation and/or erosion of base material of the metal piece. Therefore, the synergistic cooperation between the first and the second layer generates an innovative hydrogen diffusion barrier which is more efficient in preventing hydrogen diffusion with respect to what is known at the state of the art.

According to another aspect, the subject-matter disclosed herein relates to a method to provide a hydrogen diffusion barrier on a metal impeller even when subjected to stress, i.e. during operation of the impeller and/or after operation of the impeller, by applying on the metal impeller a first protective layer to prevent hydrogen diffusion and by applying a second protective layer on the first protective layer to prevent even corrosion and/or oxidation and/or erosion of the first protective layer. The application of the first and second layers is carried out at temperatures below 500° C., so that the (micro and/or macro) geometry of the metal impeller is not modified.

Reference now will be made in detail to embodiments of the disclosure, examples of which are illustrated in the drawings. The examples and drawing figures are provided by way of explanation of the disclosure and should not be construed as a limitation of the disclosure. In fact, it will be apparent to those skilled in the art that various modifications and variations can be made in the present disclosure without departing from the scope or spirit of the disclosure. In the following description, similar reference numerals are used for the illustration of figures of the embodiments to indicate elements performing the same or similar functions. Moreover, for clarity of illustration, some references may be not repeated in all the figures.

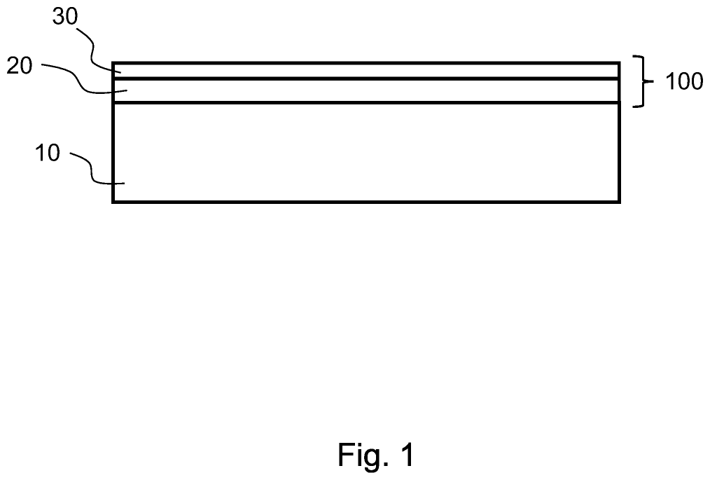

In FIG. 1 an exemplary multilayer coating 100 piece is shown. The multilayer coating 100 is configured to be applied on a metal piece 10, in particular a turbomachinery component, more in particular a turbomachinery impeller.

The multilayer coating 100 is particularly advantageous to protect the metal piece 10 when process a fluid comprising hydrogen. In fact, as it will be apparent from the following, the multilayer coating 100 is particularly advantageous for protect high-stressed parts of a turbomachinery from hydrogen diffusion and maintaining the hydrogen diffusion protection characteristic also against oxidation and/or corrosion and/or erosion.

Turbomachinery impellers are typically subject to temperature up to 250° C. due to the temperature of the working fluid (i.e. the fluid to be processed by the turbomachinery impeller) and to high strain due to the high rotary speed of the turbomachinery impeller (i.e. the materials of the turbomachinery impeller are subject to stretches due to the centrifugal force caused by rotary speed).

According to the example shown in FIG. 1, the coating 100 includes two layers 20 and 30: a first layer 20 is applied on at least a portion of the metal piece 10, preferably on the whole surface of the metal piece 10 and the second layer 30 is configured to be applied on the first layer 20, preferably on the whole surface of the first layer 20. In order to create an efficient hydrogen diffusion barrier, the first layer 20 has a hydrogen diffusion coefficient of less than 10⁻⁷ m²/s even if stressed and the second layer 30 comprises an oxide chosen between: aluminum oxide (Al2O3), titanium dioxide (TiO2) and silicon dioxide (SiO2), so that the overall hydrogen diffusion coefficient of the coating 100 (i.e. through both the first and the second layer) is less than 10⁻⁹ m²/s.

It is to be noted that the hydrogen diffusion coefficient is advantageously measured through a hydrogen permeation test, in particular according to ASTM G148-97(2018). In particular, the hydrogen diffusion coefficient is obtained from the Arrhenius equation:

$$D ( T ) = D 0 e - [ E / R \times T ]$$

where:
D(T): diffusion coefficient [m²/s],
D0: the diffusion coefficient when the temperature goes to infinity [m²/s],
E: the activation energy for diffusion [Joule/Mole],
R: Universal gas constant (8.314 [Joule/Mole*Kelvin]).

The Applicant has studied that various combinations of first and second layer 20 and 30 having the above-mentioned characteristics create an efficient hydrogen diffusion barrier for the metal piece 10 to be protected.

Moreover, the Applicant has studied a multilayer coating 100 in which the first layer 20 and the second layer 30 can be applied at temperature below 500° C., so that the metal piece 10 is not affected by geometric deformations and/or the microstructure of the metal piece 10 in not affected.

Advantageously, the first layer 20 has a thickness higher than 25 μm, in particular in a range of 25-150 μm, preferably in a range of 50-100 μm.

According to a first example, the first layer 20 may comprise an aluminum-based material, i.e. a material which has a composition of at least 50% of aluminum. According to a second example, the first layer 20 may comprise chromium nitride. According to a third example, the first layer 20 may comprise tungsten carbide, in particular tungsten carbide added with cobalt or cobalt-chrome. However, many other embodiments are possible without exiting from the scope of the present disclosure.

Moreover, as it will better explain in the following, the first and second layer 20 and 30 may be applied on the metal piece 10 according to various deposition process techniques, depending for example on the metal piece 10 geometry and/or the material of the first layer 20 and/or the material of the second layer 30.

As already explained, the multilayer coating 100 may be exposed to a process fluid comprising hydrogen, in particular the second layer 30 is configured to be exposed to a flow comprising hydrogen. Advantageously, the second layer 30 is a non-porous material, e.g. a material which presents a porosity value below 0.05%, eventually equal to 0%, according to the mercury porosimetry method or image analysis in section. It is to be noted that in any case the second layer 30 may present defects, especially when subjected to high stress in operation, in particular structural defects; however, typically, structural defects result in local damages which an increase hydrogen diffusion coefficient but does not compromise the overall functionality of the layer. More advantageously, the second layer has a thickness higher than 3 μm, in particular in a range of 3-25 μm, preferably in a range of 5-15 μm.

It is to be noted that the above-mentioned characteristics of the second layer 30, in particular the low (eventually null) porosity and the thickness of the second layer 30, make the second layer 30 particularly suitable to avoid oxidation and/or corrosion and/or erosion of the first layer 20 (if needed).

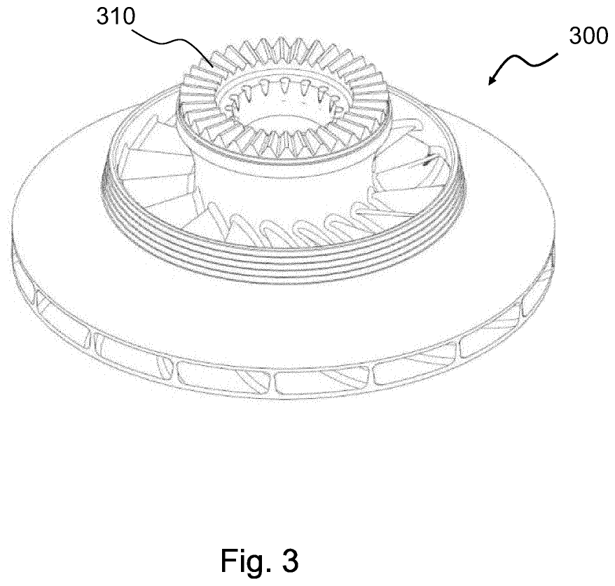

According to another aspect, the subject-matter disclosed herein relates to a turbomachinery component, in particular a turbomachinery impeller, more in particular a metal turbomachinery impeller, comprising a multilayer coating as explained above (see the exemplary impeller shown in FIG. 3).

The multilayer coating covers at least a portion of the turbomachinery component, preferably the whole surface of the turbomachinery component, in order to prevent hydrogen diffusion in the component, therefore advantageously preventing embrittlement of the turbomachinery component caused by diffusion of hydrogen in the materials when the component should be exposed to a flow comprising hydrogen, in particular when the turbomachinery impeller is configured to process (i.e. compress or expand) a fluid comprising hydrogen (eventually a fluid comprising 100% of hydrogen).

According to another aspect, the subject-matter disclosed herein relates to an innovative method 200 to prevent hydrogen diffusion in a metal piece, in particular a turbomachinery component, more in particular a turbomachinery impeller. In general, the innovative method 200 comprises the following steps “a” and “b”:
a. applying 210 a first layer on at least a portion of the metal piece using a technique chosen between: spray, immersion, physical vapor deposition (=PVD) and chemical vapor deposition (=CVD), the first layer being made of a first material low-permeable to hydrogen even when subjected to stress, and
b. applying 220 a second layer on the first layer, the second layer being made of a second material being anti-oxidation and/or anti-corrosion and/or anti-erosion,
   the application 210 of step “a” and the application 220 of step “b” being performed at temperature below 500° C.

As already explained, the first layer is made of a material which has a hydrogen diffusion coefficient less than 10⁻⁷ m²/s even when subjected to stress, therefore resulting in a layer that is low-permeable to hydrogen. In particular, the innovative method aims at preventing embrittlement of metal pieces caused by diffusion of hydrogen in the materials when the metal piece should be exposed to a flow comprising hydrogen, in particular when the metal piece is a turbomachinery impeller configured to process (i.e. compress or expand) a fluid comprising hydrogen (eventually a fluid comprising 100% of hydrogen).

According to step “a” of the innovative method 200, the first layer may be applied on at least a portion of the metal piece, preferably on the whole surface of the metal piece, according to various deposition process techniques.

As already explained, the first layer may be applied by spraying the first material on the surface of the metal piece (“spray deposition”) or by dipping of the metal piece into a bath coating (“dip-coating” or “immersion coating”) or by vaporizing of the first material, typically in a vacuum, and depositing onto the surface of the metal piece (“physical vapor deposition” or “PVD”) or by depositing the first material on the surface of the metal piece by chemical reaction in a gas (“chemical vapor deposition” or “CVD”) or by depositing the first material on the surface of the metal piece by chemical reaction in a gas using electrical energy to generate plasma useful to supply energy to perform chemical reaction (“plasma assisted chemical vapor deposition” or “PACVD”).

It is to be noted that chemical vapor deposition may be performed both at high temperature and low temperature; advantageously, the first layer is applied using low-temperature chemical vapor deposition, in particular at a temperature in the range 0-350° C.

Advantageously, the second layer is applied using chemical deposition in vapor using electrical energy to generate plasma useful to supply energy to perform the chemical reaction (for example “plasma assisted chemical vapor deposition” or “PACVD” or “plasma enhanced chemical vapor deposition” or “PECVD” or “induction plasma enhanced chemical vapor deposition” or “IPECVD”). In other words, the second layer is applied using one of those low-temperature chemical vapor deposition, in particular to avoid damaging (in particular burning) the first layer already applied on the metal piece.

According to a preferred embodiment, the low-temperature chemical vapor deposition is performed at a temperature in the range 0-350° C.

According to a preferred embodiment, the low-temperature chemical vapor deposition is performed at a pressure in the range 0-1 bar.

1. A multilayer coating for a metal piece, in particular a turbomachinery component, more in particular a turbomachinery impeller, the coating comprising:
a first layer to be applied on at least a portion of the metal piece, the first layer having a hydrogen diffusion coefficient of less than 10⁻⁷ m²/s even when subjected to stress, the hydrogen diffusion coefficient being measured through a hydrogen permeation test; and
a second layer to be applied on the first layer, the second layer comprising an oxide chosen between: aluminum oxide (Al2O3), titanium dioxide (TiO2) and silicon dioxide (SiO2), wherein the second layer is configured to be exposed to a process fluid comprising hydrogen, and wherein the first layer and the second layer are applied at temperature below 500° C.

2. The multilayer coating of claim 1, wherein the second layer is configured to avoid oxidation.

3. The multilayer coating of claim 1, wherein the second layer is configured to avoid corrosion.

4. The multilayer coating of claim 1, wherein the second layer is configured to avoid erosion.

5. The multilayer coating of claim 1, wherein the second layer has a thickness in the range of 3-15 μm.

6. The multilayer coating of claim 1, wherein the first layer comprises an aluminum-based material.

7. The multilayer coating of claim 1, wherein the first layer comprises chromium nitride.

8. The multilayer coating of claim 1, wherein the first layer comprises tungsten carbide, in particular tungsten carbide added with cobalt or cobalt-chrome.

9. A method to prevent hydrogen diffusion in a metal piece, in particular a turbomachinery component, more in particular a turbomachinery impeller, the method comprising the steps of:
a. applying a first layer on at least a portion of the metal piece using a technique chosen between: spray, immersion, physical vapor deposition (PVD) and chemical vapor deposition (CVD), the first layer being made of a first material low-permeable to hydrogen even when subjected to stress; and
b. applying a second layer on the first layer, the second layer being made of a second material being anti-oxidation and/or anti-corrosion and/or anti-erosion, wherein the application of step “a” and the application of step “b” are performed at temperature below 500° C.

10. The method according to claim 9, wherein the second layer is applied using chemical vapor deposition (CVD).

11. The method according to claim 10, wherein the second layer is applied using low-temperature chemical vapor deposition, in particular plasma assisted chemical vapor deposition (PACVD) or plasma enhanced chemical vapor deposition (PECVD) or induction plasma enhanced chemical vapor deposition (IPECVD), in particular temperature in a range of 0-350° C.

12. A turbomachinery component, in particular a turbomachinery impeller, comprising a multilayer coating according to claim 1, wherein the multilayer coating covers at least a portion of the turbomachinery component.
